(19) United States
(12) Patent Application Publication
(10) Pub. No.: US 2026/0157046 A1
(43) Pub. Date: Jun. 4, 2026

(54) DISPLAY PANEL AND DISPLAY DEVICE

(71) Applicants: Mianyang HKC Optoelectronics Technology Co., Ltd., Mianyang (CN); HKC Corpotation Limited, Shenzhen (CN)

(72) Inventors: QIN LIANG, Mianyang (CN); Yangling TANG, Mianyang (CN); Zhisheng XIE, Mianyang (CN); Xiufeng ZHOU, Mianyang (CN); Haijiang YUAN, Mianyang (CN)

(21) Appl. No.: 19/389,027

(22) Filed: Nov. 14, 2025

(30) Foreign Application Priority Data
Nov. 29, 2024 (CN) 202411737132.2

(51) Int. Cl. H10K 59/122; H10K 59/38; H10K 59/80

(52) U.S. Cl. CPC H10K 59/122; H10K 59/38; H10K 59/8792

(57) ABSTRACT

A display panel and display device are disclosed. The display panel includes a substrate, a pixel driving layer, a pixel definition layer, a plurality of light-emitting elements, an encapsulation layer, a color filter layer. The pixel driving layer is disposed on the substrate; the pixel definition layer is disposed on the pixel driving layer; a plurality of light-emitting elements are disposed in an array on the pixel driving layer and each light-emitting element is respectively located within each opening; the encapsulation layer is disposed on the light-emitting element layer; the color filter layer is disposed on the encapsulation layer; the encapsulation layer includes an organic encapsulation layer, the organic encapsulation layer is provided with a plurality of first grooves at positions corresponding to the plurality of openings; the color filter layer includes a plurality of color filter portions, and each color filter portion is disposed within each first groove.

### CROSS-REFERENCE TO RELATED APPLICATIONS

The present application claims the priority and benefit of Chinese patent application number 2024117371322, titled “Display Panel and Display Device” and filed on Nov. 29, 2024 with China National Intellectual Property Administration, the entire contents of which are incorporated herein by reference.

### TECHNICAL FIELD

The present application relates to the technical field of display, and more particularly relates to a display panel and a display device.

### BACKGROUND

The description provided in this section is intended for the mere purpose of providing background information related to the present application but does not necessarily constitute prior art.

With the continuous development of Organic Light-Emitting Diode (hereinafter referred as OLED) display technology, OLED display technology is increasingly used in displays such as smartphones, tablets, computers, and televisions. OLED displays have the advantages of being thin and light, high contrast, fast response, wide viewing angle, high brightness, and full color. In order to reduce the reflectivity of external light in OLED displays, the current mainstream solution is to attach a circular polarizer to the light-emitting surface of the OLED display. However, this solution reduces the light-emitting effect due to the large light loss of the circular polarizer. Another solution is to set a color filter layer on the light-emitting surface of the OLED display to improve the light-emitting efficiency. A black matrix (hereinafter referred to as BM) may be set to reduce the effect of ambient light reflection in the OLED display, and the thickness of the entire display panel may also be reduced.

However, when fabricating color filters on display panels, after the black matrix process is completed and during the formation of the color filter layer by depositing color filter materials, the presence of the black matrix may easily cause “ox-horn” defects due to stacking at the overlapping positions with the color filter sections, leading to display unevenness and other issues.

### SUMMARY

An objective of the present application is to provide a display panel and a display device, to improve the color purity and uniformity of each position of the color filter part within the same opening.

Disclosed in the present application is a display panel, the display panel includes a substrate, a pixel driving layer, a pixel definition layer, a plurality of light-emitting elements, an encapsulation layer and a color filter layer. The pixel driving layer is disposed on the substrate, a pixel definition layer is disposed on the pixel driving layer, and is formed with a plurality of openings, a plurality of light-emitting elements are disposed in an array on the pixel driving layer, and each of the plurality of light-emitting elements is respectively located within each of the plurality of openings. The encapsulation layer is disposed on the light-emitting element layer, the color filter layer is disposed on the encapsulation layer; the encapsulation layer includes an organic encapsulation layer, the organic encapsulation layer is provided with a plurality of first grooves at positions corresponding to the openings; the color filter layer includes a plurality of color filter portions, and each of the plurality of color filter portions is disposed within each of the plurality of first grooves.

Embodiments of the present application further disclose a display panel, the display panel includes a driving circuit and a display panel, the driving circuit is configured to drive the display panel to perform the display operation; the display panel includes a substrate, a pixel driving layer, a pixel definition layer, a plurality of light-emitting elements, an encapsulation layer, and a plurality of color filter layers, a plurality of the pixel definition layers are disposed on the pixel driving layer, and are formed with a plurality of openings; the plurality of light-emitting elements are disposed in an array on the pixel driving layer, and each of the plurality of light-emitting elements is respectively located within each of the plurality of openings; the encapsulation layer is disposed on the light-emitting element layer; the color filter layer is disposed on the encapsulation layer; the encapsulation layer includes an organic encapsulation layer, the organic encapsulation layer is provided with a plurality of first grooves at positions corresponding to the openings; the color filter layer includes a plurality of color filter portions, and each of the plurality of color filter portions is disposed within each of the plurality of first grooves.

### BRIEF DESCRIPTION OF DRAWINGS

The accompanying drawings are used to provide a further understanding of the embodiments according to the present application, and constitute a part of the specification. They are used to illustrate the embodiments according to the present application, and explain the principles of the present application in conjunction with the text description. Apparently, the drawings in the following description merely represent some embodiments of the present disclosure, and for those having ordinary skill in the art, other drawings may also be obtained based on these drawings without investing creative. In the drawings:

FIG. 1 is a schematic diagram of the display panel according to the first embodiment of the present application.

FIG. 2 is a schematic cross-sectional view of FIG. 1 along the cutting line AA.

FIG. 3 is a schematic diagram of the display panel according to the second embodiment of the present application.

FIG. 4 is a schematic diagram of the display panel according to the third embodiment of the present application.

FIG. 5 is a schematic diagram of a display panel according to the third embodiment of the present application.

FIG. 6 is a schematic diagram of another display panel according to the third embodiment of the present application.

FIG. 7 is a schematic diagram of the display device of the present application.

### DETAILED DESCRIPTION OF EMBODIMENTS

It should be understood that the terms used herein, the specific structures and functional details disclosed therein are merely representative for describing some specific embodiments, but the present application may be implemented in many alternative forms and should not be construed as being limited to only these embodiments described herein.

As used herein, terms “first”, “second”, or the like are merely used for illustrative purposes, and shall not be construed as indicating relative importance or implicitly indicating the number of technical features specified. Thus, unless otherwise specified, the features defined by “first” and “second” may explicitly or implicitly include one or more of such features. Terms “multiple”, “a plurality of”, and the like mean two or more. In addition, terms “up”, “down”, “left”, “right”, “vertical”, and “horizontal”, or the like are used to indicate orientational or relative positional relationships based on those illustrated in the drawings. They are merely intended for simplifying the description of the present disclosure, rather than indicating or implying that the device or element referred to must have a particular orientation or be constructed and operate in a particular orientation. Therefore, these terms are not to be construed as restricting the present disclosure. For those of ordinary skill in the art, the specific meanings of the above terms as used in the present application can be understood depending on specific contexts.

The present application is described in detail below with reference to the accompanying drawings and some optional embodiments.

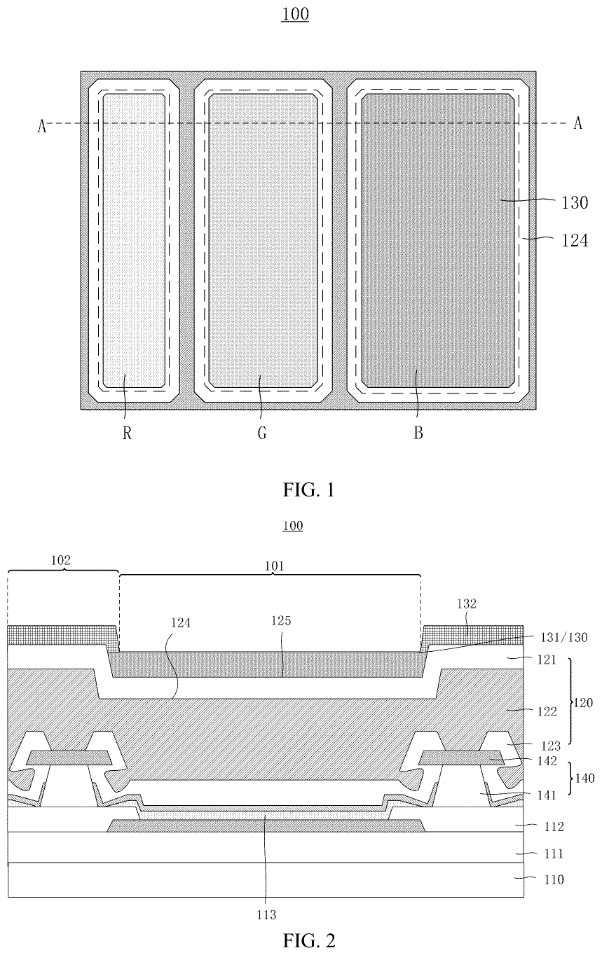

FIG. 1 is a schematic diagram of a display panel according to the first embodiment of the present application, and FIG. 2 is a cross-sectional schematic diagram of FIG. 1 along the cutting line AA. As shown in FIGS. 1-2, The present application discloses a display panel 100, including a substrate 110, a pixel driving layer 111, a plurality of pixel defining layers 112, a plurality of light-emitting elements 113, an encapsulation layer 120, and a color filter layer 130, where the pixel driving layer 111 is disposed on the substrate 110. A plurality of pixel defining layers 112 are disposed on the pixel driving layer 111, and the plurality of pixel defining layers 112 are spaced apart to form a plurality of openings; the plurality of light-emitting elements 113 are disposed in an array on the pixel driving layer 111 and are respectively located within the plurality of openings; the encapsulation layer 120 is disposed on the light-emitting element 113; the color filter layer 130 is disposed on the encapsulation layer 120, and the encapsulation layer 120 includes an organic encapsulation layer 122, and the organic encapsulation layer 122 is provided with a first groove 124 at a position corresponding to the opening; the color filter layer 130 includes a plurality of color filter portions 131, and each of the plurality of color filter portions 131 is correspondingly disposed in the first groove 124.

When the black matrix 132 is formed, according to the present application, there is no “ox-horn” defect in the color filter portions 131 caused by the black matrix 132 by providing the first groove 124 in the organic encapsulation layer 122 and arranging the color filter portions 131 within the first groove 124 located at the position of the opening. Furthermore, the provision of the first groove 124 enhances the flatness of the color filter portions 131, mitigating variations in spectral characteristics and brightness across different positions of the color filter portions 131, because these variations are typically caused by thickness disparities between the center and edges of the color filter portions 131. This helps to improve the display effect under large viewing angles and reduce the color separation phenomenon caused by ambient light reflecting off the display panel 100.

Specifically, during the process of forming the color filter portions 131 after fabricating the black matrix 132 in the display panel 100, since the black matrix 132 has a certain thickness, the overlapping position between the color filter portions 131 and the black matrix 132 is prone to forming an “ox-horn” shape, that is, causing uneven film layers of the color filter portions 131. In particular, at the edge positions of the black matrix 132, the upper surface of the color filter portions 131 exhibits obvious protrusions, which results in non-uniform film layers on the upper surface of the color filter portions 131. In the present application, by shifting the position of each color filter portion 131 downward and forming a relatively flat film layer below the color filter portion 131 through the first groove 124 provided on the organic encapsulation layer 122, the formation of the color filter portion 131 is no longer affected by the black matrix 132, which eliminates the stacked “ox-horn” defect caused by the interaction between the color filter portion 131 and the black matrix 132.

Specifically, the pixel driving layer 111 is provided with pixel driving circuits for driving the light-emitting elements 113, including thin-film transistors, data driving lines, scanning lines, etc. The above-mentioned thin-film transistors, data driving lines, and scanning lines are formed through multiple layers of metal films and insulating films. A planarization layer is typically disposed on the pixel driving layer 111, and the subsequent light-emitting elements 113 and pixel defining layers 112 are respectively disposed on the planarization layer.

Specifically, the encapsulation layer 120 covers the light-emitting elements 113 and the pixel defining layers 112, and is configured to encapsulate the light-emitting elements 113 to prevent external moisture from entering. In the present embodiment, the encapsulation layer 120 employs a thin-film encapsulation technology, which is a stacked layer formed by multiple layers of inorganic and organic materials. The organic encapsulation layer 122 is formed of an organic material. The encapsulation layer 120 further includes a first inorganic layer 121 disposed on the organic encapsulation layer 122. The second inorganic layer 123 covers the first groove 124 to form a second groove 125, and the color filter portion 131 is disposed within the second groove 125. The first inorganic layer 121 is formed of an inorganic material, and the thickness of the first inorganic layer 121 is generally much less than that of the organic encapsulation layer 122.

In the present embodiment, by forming the first groove 124 in the organic encapsulation layer 122, the second groove 125 is formed at a position corresponding to the first groove 124 when the first inorganic layer 121 is formed, and the color filter portion 131 is disposed within the second groove 125. Relatively speaking, the organic encapsulation layer 122 has a relatively thick film thickness, allowing a first groove 124 with a relatively great depth to be formed in the organic encapsulation layer 122 to accommodate the color filter portion 131.

In the present embodiment, the encapsulation layer 120 may adopt a three-layer film stacking method for encapsulation. The encapsulation layer 120 includes a first inorganic layer 121, an organic encapsulation layer 122, and a second inorganic layer 123. The second inorganic layer 123 covers the light-emitting elements 113 and is positioned below the organic encapsulation layer 122. The organic encapsulation layer 122 is disposed on the second inorganic layer 123, and the first inorganic layer 121 is disposed on the organic encapsulation layer 122. That is, the color filter layer 130 is in direct contact with the second inorganic layer 123. Relatively speaking, in the present embodiment, it is worth mentioning that the impact on the organic encapsulation layer 122 is minimal due to a relatively great thickness of the organic encapsulation layer 122 by forming the first groove 124 in the organic encapsulation layer 122.

The display panel 100 further includes a black matrix 132 specifically disposed on the first inorganic layer 121 and within the orthographic projection of the substrate 110. The black matrix 132 overlaps with the pixel defining layer 112. The primary functions of the black matrix 132 include preventing ambient light from entering the interior of the display panel 100 and causing light reflection issues, as well as isolating adjacent color filter portions 131 to prevent optical crosstalk.

In the present embodiment, the black matrix 132 is primarily disposed in the non-opening area 102, that is, on the first inorganic layer 121 at positions other than the first groove 124. In terms of specific manufacturing processes, after forming the first inorganic layer 121, the color filter portion 131 may be formed first, followed by the black matrix 132. This approach avoids defects in the color filter portion 131 caused by forming the black matrix 132 first.

Specifically, a thickness of the organic encapsulation layer 122 in the area of the first groove 124 is less than that in the non-first groove area. Generally, a depth of the first groove 124 needs to be greater than or equal to a thickness of the color filter layer 130 or the color filter portion 131. It should be understood that, under normal circumstances, a depth of the first groove 124 is equal to that of the second groove 125. When not considering a difference in the film thickness of the first inorganic layer 121 inside and outside the first groove 124, it is generally assumed that a depth of the first groove 124 is equal to that of the second groove 125.

When a thickness of the organic encapsulation layer 122 is sufficient, a depth of the first groove 124 may be set slightly greater than a thickness of the color filter portion 131, which ensures that, after forming the color filter portion 131, the surface of the color filter portion 131 distal from the substrate 110 is slightly lower than the first inorganic layer 121. This configuration provides more flexibility in the process of forming the black matrix 132. For example, the black matrix 132 may be formed first by depositing the black matrix material across the entire surface, including the area of the second groove 125. The black matrix material within the second groove 125 is then removed through etching, followed by the formation of the color filter portion 131 within the second groove 125. Even if a small amount of black matrix material remains on the sidewalls of the second groove 125, this approach has minimal impact. For another example, the color filter portion 131 may be formed first by depositing the color filter material within the second groove 125, followed by the formation of the black matrix 132. Additionally, a protective layer may be formed on the color filter portion 131 before depositing the black matrix 132 material to prevent damage to the color filter portion 131 during the etching process of the black matrix 132.

In the present application, the surface of each film layer away from the substrate 110 is called as the upper surface, and the surface of each film layer close to the substrate 110 is called the lower surface. In the following description, terms of “the upper surface” and “the lower surface” are used instead.

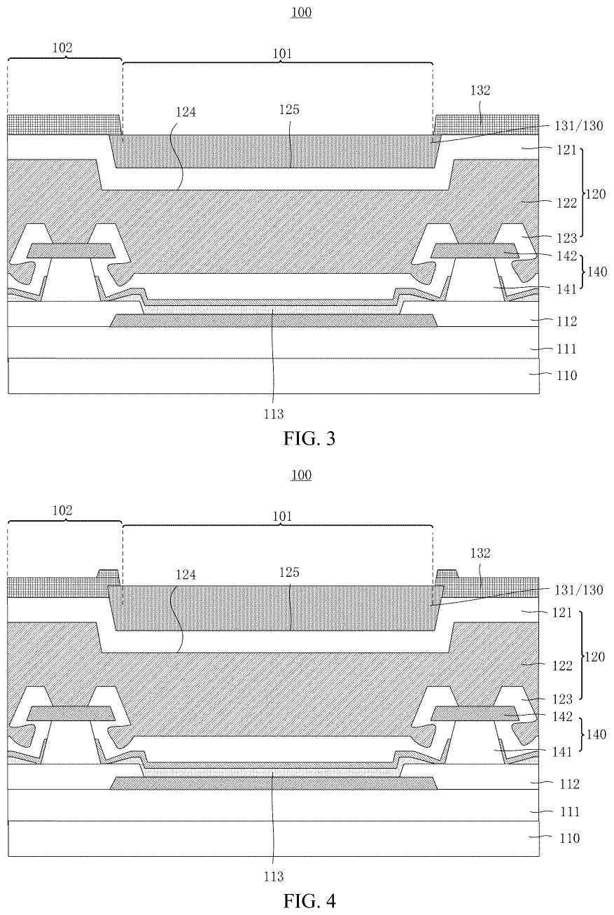

FIG. 3 is a schematic diagram of the display panel according to the second embodiment of the present application. As shown in FIG. 3, considering that an actual film thickness of the color filter portion 131 is relatively great, while a thickness of the organic encapsulation layer 122 is limited, in one embodiment, a depth of the second groove 125 is equal to a thickness of the color filter portion 131. The surface of the color filter portion 131 distal from the substrate 110 is coplanar with the surface of the first inorganic layer 121 at non-groove positions distal from the substrate 110. That is, the upper surface of the color filter portion 131 is coplanar with the upper surface of the first inorganic layer 121.

In the present embodiment, by improving the depth of the second groove 125 to exactly match the thickness of the color filter portion 131, the upper surface of the color filter portion 131 is flush with the upper surface of the first inorganic layer 121, thereby enhancing the flatness of the color filter portion 131. During the formation of the color filter portion 131, the color filter portion 131 at non-first groove positions needs to be etched away. By setting the thickness of the color filter portion 131 to be less than or equal to the depth of the second groove 125 (which is also be referred to as the depth of the first groove 124), the slope of the color filter portion 131 on the sidewalls of the second groove 125 becomes relatively shallow, thereby enabling easier etching removal. This ensures that the thickness of the edge portion of the color filter portion 131 is more consistent with that of the central portion. As a result, the light transmission thickness through various positions of the color filter portion 131 is more uniform, leading to more homogeneous spectral characteristics and brightness at each position. This maintains display color purity and uniformity. Additionally, a flatter surface of the color filter portion 131 reduces light scattering and reflection caused by surface irregularities.

In a specific embodiment, the color filter portion 131 includes a red filter portion (R), a green filter portion (G), and a blue filter portion (B). One red filter portion, one green filter portion, and one blue filter portion adjacent to each other constitute three sub-pixels in one pixel. The red filter portion is disposed corresponding to the red sub-pixel, the green filter portion is disposed corresponding to the green sub-pixel, and the blue filter portion is disposed corresponding to the blue sub-pixel.

When the color filter portions 131 of different colors have varying thicknesses, the depths of the corresponding first grooves 124 formed in the organic encapsulation layer 122 are adjusted accordingly. For example, if the red filter portion is the thickest and the blue filter portion is the thinnest, a relatively thick first groove 124 is provided at the position corresponding to the red filter portion, a relatively thin first groove 124 is provided at the position corresponding to the blue filter portion, and a first groove 124 of intermediate depth is provided at the position corresponding to the green filter portion. This configuration ensures that the upper surfaces of the red, blue, and green filter portions are coplanar with the upper surface of the first inorganic layer 121.

Further, considering the influence of the sidewalls of the second groove 125, when the color filter material is formed over an entire surface, a film layer with a certain slope is also formed on the sidewalls of the second groove 125, extending from the second groove 125 toward the non-second groove area. Therefore, in the present embodiment, the black matrix 132 partially overlaps with the color filter portion 131 in the orthographic projection on the substrate 110.

By increasing a width of the black matrix 132 such that the black matrix 132 partially overlaps with a film layer portion of the color filter portion 131 located at an edge position, thereby achieving shielding of an uneven film layer at an edge of the color filter portion 131, preventing the film layer portion from being used for display, thereby avoiding a poor display effect caused by unevenness of the film layer.

Specifically, the width of the second groove 125 is greater than or equal to the width of the opening area 101, so that the width of the color filter portion 131 is also greater than that of the opening area 101. This ensures that the transitional positions with film thickness variations of the color filter portion 131 do not lie within the opening area 101, thereby improving the display effect without reducing the pixel aperture.

Specifically, the overlapping width between the black matrix 132 and the color filter portion 131 should not extend beyond the non-opening area 102. More specifically, the widest part of the black matrix 132 does not overlap with the effective light-emitting area of the light-emitting element 113, ensuring that the black matrix 132 does not reduce the aperture size of the sub-pixels.

FIG. 4 is a schematic diagram of a display panel according to a third embodiment of the present application. Referring to FIG. 4, the present application further discloses a display panel 100. The display panel 100 includes a substrate 110, a pixel driving layer 111, a pixel definition layer 112, a plurality of light-emitting elements 113, an encapsulation layer 120, and a color filter layer 130. The pixel driving layer 111 is disposed on the substrate 110, and the pixel definition layer 112 is disposed on the pixel driving layer 111 and has a plurality of openings formed therein; a plurality of the light-emitting elements 113 are disposed in an array on the pixel driving layer 111, with each of the plurality of light-emitting elements 113 disposed within each of the plurality of openings. The encapsulation layer 120 is provided over the light-emitting element layer 113, and the color filter layer 130 is disposed over the encapsulation layer 120. The encapsulation layer 120 includes an organic encapsulation layer 122, and the organic encapsulation layer 122 is provided with a first groove 124 at a position corresponding to the opening. The color filter layer 130 includes a plurality of color filter portions 131, and the color filter portions 131 are disposed within the first groove 124.

In the present embodiment, due to the insufficient thickness of the organic encapsulation layer 122, a depth of the second groove 125 is limited, such that the upper surface of the color filter portion 131 is higher than the upper surface of the first inorganic layer 121. For example, the display panel 100 is formed using a maskless evaporation technology. In view of the space occupied by the overhang structure 140 in the non-opening region 102, when the first groove 124 is formed in the organic encapsulation layer 122, the width of the first groove 124 exceeds that of the opening region 101 and may also occupy a portion of the non-opening area 102, thereby causing the depth of the first groove 124 not be too deep, consequently resulting in the upper surface of the color filter portion 131 being positioned slightly higher than the upper surface of the first inorganic layer 121.

Specifically, the display panel 100 further includes a plurality of overhang structures 140 disposed at intervals on the pixel definition layer 112, which is configured to separate two adjacent light-emitting elements 113. The light-emitting element 113 generally includes a bottom electrode, a light-emitting functional layer, and a top electrode. The overhang structure 140 generally includes a conductive layer 141 and an insulating layer 142. In the non-opening area 102, the width of the insulating layer 142 is greater than that of the conductive layer 141. During the full-surface evaporation of the light-emitting elements 113, the insulating layer 142 blocks the deposition, preventing the light-emitting functional layer of the light-emitting element 113 from forming below the insulating layer 142. This ensures that the light-emitting functional layer of each light-emitting element 113 is not connected to those of adjacent light-emitting elements, nor to redundant light-emitting functional layers on the overhang structure 140.

Specifically, the depth of the second groove 125 is less than a thickness of the color filter portion 131. A surface of the color filter portion 131 distal from the substrate 110 is elevated above a surface of the first inorganic layer 121 at a non-groove position distal from the substrate 110.

In the present embodiment, by adjusting a thickness of the color filter portion 131, the upper surface of the color filter portion 131 is slightly elevated above the height of the upper surface of the first inorganic layer 121. This configuration ensures that even if there are height variations on the upper surface of the color filter portion 131 at the sidewall positions of the second groove 125, fewer planarization materials are required to planarize the color filter layer 130 during subsequent etching processes. Relatively speaking, the solution of the present embodiment is more suitable for scenarios where, when the heights of the color filter portions 131 of different colors vary and it is impossible to flush the upper surfaces of multiple color filter portions 131, the upper surfaces of the color filter portions 131 may be slightly higher than the upper surface of the first inorganic layer 121.

Specifically, in the orthographic projection of the substrate 110, the black matrix 132 partially overlaps with the color filter portion 131. A surface of the black matrix 132 distal from the substrate 110 is elevated above the surface of the color filter portion 131 distal from the substrate 110.

In the present embodiment, the black matrix 132 partially overlaps with the edge film layers of the color filter portion 131 to mask uneven film layers at the edges of the color filter portion 131. This prevents these uneven regions from being used for display, avoiding poor display effects caused by film layer irregularities. Additionally, the upper surface of the color filter portion 131 should be lower than the upper surface of the black matrix 132.

Specifically, the difference in height between the surface of the color filter portion 131 distal from the substrate 110 and the surface of the first inorganic layer 121 at the non-groove position distal from the substrate 110 is less than or equal to 1 μm.

In the present embodiment, the height of the color filter portion 131 is slightly elevated above the upper surface height of the first inorganic layer 121 at the non-opening area 102. This configuration prevents significant edge height variations in the color filter portion 131, particularly at the sidewall positions of the second groove where the thickness of the color filter portion 131 gradually changes. By setting the thickness of the color filter portion 131 to exceed the depth of the second groove, the color filter material with thickness variations extending beyond the second groove into the non-display area may be removed during subsequent material removal processes.

Further, considering the influence of the sidewalls of the second groove 125, when forming the color filter material over the entire surface, a film layer with a certain slope is also formed on the sidewalls of the second groove 125, the film layer which extends from the second groove 125 to the non-second groove area. Therefore, in the present embodiment, the sidewalls of the first groove 124 and the second groove 125 may be configured as multi-stepped to reduce the slope of the sidewalls of the second groove.

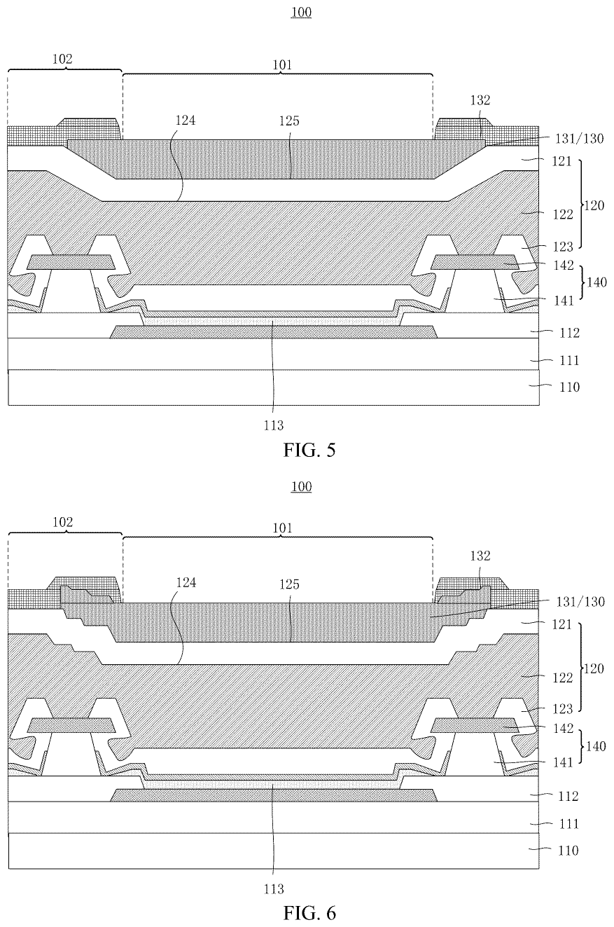

FIG. 5 is a schematic diagram of a display panel according to the third embodiment of the present application, and FIG. 6 is a schematic diagram of another display panel according to the third embodiment of the present application. As shown in FIGS. 5 to 6, through photolithography or imprinting techniques, the sidewalls of the second groove are configured to have a gradually changing slope, with the region of gradual slope change located within the non-opening area. Specifically, the sidewall slope of the second groove is between 30 degrees and 80 degrees, so that the film layer of the color filter portion changes gradually at the transition position from the second groove to the non-groove area, avoiding significant changes in the film layer of the color filter portion. As shown in FIG. 6, multiple stepped surfaces may also be provided to achieve the same purpose, i.e., causing the color filter portion to gradually rise along the sidewalls of the second groove. It is worth mentioning that ideally, as shown in the schematic diagram of FIG. 4, all color filter materials in non-groove areas are removed during the photolithography of the color filter portion. However, influenced by the sidewalls of the second groove, the film layer of the color filter portion starts to change near the sidewalls of the second groove. Increasing the sidewall slope of the second recess results in a steeper gradient in the thickness of the color filter layer adjacent to the sidewall of the second recess. This phenomenon leads to suboptimal film formation at the periphery of the second recess, thereby compromising the uniformity and performance of the color filter layer. Therefore, in the present embodiment, the sidewalls of the second groove are further modified to ensure that the film layer of the color filter portion transitions gradually from the second groove to the non-groove area. Additionally, the region where the film thickness changes is shifted toward the non-groove area. During the subsequent manufacturing process of the black matrix, this region is covered by the black matrix to block the emitted light, thereby enhancing the display quality of the display panel.

Specifically, during the formation of the first groove 124 in the organic encapsulation layer 122, it may be achieved either by etching or by embossing with a mold. For the etching method, a halftone mask technique is required to form multiple first grooves 124 in the organic encapsulation layer 122. For the mold embossing technique, embossing templates with different thicknesses may be configured to make the multiple first grooves 124 have different depths, so as to meet the requirements of different thicknesses of the color filter portions 131 for different colors.

Specifically, the manufacturing method of the display panel 100 of the present application includes: providing a substrate 110, forming a pixel driving layer 111 on the substrate 110, forming a pixel definition layer 112 on the pixel driving layer 111, performing a patterning process on the pixel definition layer 112 to form a plurality of openings at positions where the light-emitting elements 113 are located, retaining the pixel definition layer 112 in a non-opening area 102, forming an overhang structure 140 on the pixel definition layer 112, and using the overhang structure 140 to form a plurality of light-emitting elements 113, where two adjacent light-emitting elements 113 are separated by the overhang structure 140. After completing the fabrication process of the light-emitting elements 113, an encapsulation layer 120 is formed. During the formation of the organic encapsulation layer 122 of the encapsulation layer 120, a plurality of first recesses 124 are formed in the opening region 101. After depositing the first inorganic layer 121 of the encapsulation layer 120, the first inorganic layer 121 conformally covers the first recesses 124 to define a plurality of second recesses 125. Upon completion of the encapsulation layer 120 process, the color filter layer 130 is fabricated by sequentially forming color filter elements 131 within the second groove 125 and a black matrix 132 overlying the color filter elements 131. Subsequent processes include depositing additional functional layers and attaching external modules to finalize the manufacturing of the display panel 100.

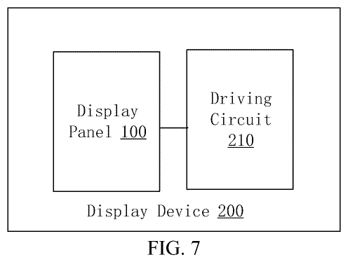

FIG. 7 is a schematic diagram of a display device according to the present application. As shown in FIG. 7, the present application further discloses a display device 200, which includes a driving circuit 210 and the display panel 100 according to any of the foregoing embodiments. The driving circuit 210 is configured to drive the display panel 100 to display images.

The foregoing is a further detailed description of the present application with reference to some specific optional implementations, but it cannot be determined that the specific implementation of the present application is limited to these implementations. For those having ordinary skill in the technical field to which the present application pertains, several deductions or substitutions may be made without departing from the concept of the present application, and all these deductions or substitutions should be regarded as falling in the scope of protection of the present application.

What is claimed is:

1. A display panel, comprising:
a substrate;
a pixel driving layer, disposed on the substrate;
a pixel definition layer, disposed on the pixel driving layer, and is formed with a plurality of openings;
a plurality of light-emitting elements, disposed in an array on the pixel driving layer, and each of the plurality of light-emitting elements is respectively located within each of the plurality of openings;
an encapsulation layer, disposed on the light-emitting element ; and
a color filter layer, disposed on the encapsulation layer,
wherein the encapsulation layer comprises an organic encapsulation layer, the organic encapsulation layer is provided with a plurality of first grooves at positions corresponding to the plurality of openings; a color filter layer comprises a plurality of color filter portions, and each of the plurality of color filter portions is disposed within each of the plurality of first grooves.

2. The display panel according to claim 1, wherein the display panel further comprises a plurality of black matrixes, the plurality of the black matrixes are disposed on the encapsulation layer; the plurality of black matrixes overlaps with the pixel definition layer in the orthographic projection on the substrate, the encapsulation layer further comprises a first inorganic layer, and the first inorganic layer is disposed on the organic encapsulation layer, the first inorganic layer covers the plurality of first grooves to form a plurality of second grooves, and each of the plurality of color filter portions is disposed within each of the plurality of second grooves.

3. The display panel according to claim 2, wherein a depth of each of the second grooves is equal to a thickness of each of the plurality of color filter portions; a surface of each of the plurality of color filter portions distal from the substrate is coplanar with a surface of the first inorganic layer at a non-groove position distal from the substrate.

4. The display panel according to claim 3, wherein each of the plurality of black matrix partially overlaps with each of the plurality of color filter portions in the orthographic projection of the substrate.

5. The display panel according to claim 2, wherein a depth of each of the second grooves is less than a thickness of each of the color filter portions; a surface of each color filter portion distal from the substrate is elevated above a surface of the first inorganic layer at a non-groove position distal from the substrate.

6. The display panel according to claim 5, wherein each black matrix partially overlaps with each color filter portion in the orthographic projection of the substrate; a surface of each black matrix distal from the substrate is elevated above the surface of each color filter portion distal from the substrate.

7. The display panel according to claim 5, wherein a difference between a height of the surface of each color filter portion distal from the substrate and a height of the surface of the first inorganic layer at the non-groove position distal from the substrate is less than or equal to 1 μm.

8. The display panel according to claim 5, wherein a radial width of each of the second grooves is greater than or equal to a width of each of the plurality of openings; in the orthographic projection on the substrate, each of the second grooves partially overlaps with each of the pixel definition layers.

9. The display panel according to claim 2, wherein the display panel further comprises a plurality of overhanging structures, the plurality of overhanging structures are disposed at intervals on the pixel definition layers and are configured to separate two adjacent one of the plurality of light-emitting elements; the encapsulation layer also comprises a plurality of second inorganic layers, a plurality of second inorganic layers are located below the organic encapsulation layer, the plurality of second inorganic layers are disposed in a one-to-one correspondence with the plurality of light-emitting elements and cover the light-emitting elements.

10. The display panel according to claim 9, wherein each of the plurality of overhanging structures comprises a conductive layer and an insulating layer, the insulating layer is disposed on the conductive layer, and a width of the insulating layer is greater than that of the conductive layer.

11. The display panel according to claim 9, wherein a depth of each of the plurality of second grooves is less than a thickness of each of the plurality of color filter portions, a surface of each of the plurality of color filter portions distal from the substrate is elevated above a surface of the first inorganic layer at a non-groove position distal from the substrate.

12. The display panel according to claim 9, wherein a slope between 30 degrees and 80 degrees is provided on each of the two sidewalls of each of the plurality of second grooves; the slope is located at the non-opening position.

13. The display panel according to claim 1, wherein each of the plurality of color filter portions comprises a red filter portion, a green filter portion, and a blue filter portion; a thickness of the red filter portion is greater than that of the green filter portion, and a thickness of the green filter portion is greater than that of the blue filter portion; a depth of each first groove corresponding to the red filter portion is greater than that of each first groove corresponding to the green filter portion; a depth of each first groove corresponding to the green filter portion is greater than that of each first groove corresponding to the blue filter portion.

14. A display device, comprising a driving circuit and a display panel, wherein the driving circuit is configured to drive the display panel to display; the display panel comprises a substrate, a pixel driving layer, a pixel definition layer, a plurality of light-emitting elements, an encapsulation layer, and a plurality of color filter layers; a plurality of the pixel definition layers are disposed on the pixel driving layer, and are formed with a plurality of openings; the plurality of light-emitting elements are disposed in an array on the pixel driving layer, and each of the plurality of light-emitting elements is respectively located within each of the plurality of openings; the encapsulation layer is disposed on the light-emitting element layer; the color filter layer is disposed on the encapsulation layer; the encapsulation layer comprises an organic encapsulation layer, the organic encapsulation layer is provided with a plurality of first grooves at positions corresponding to the plurality of openings; a color filter layer comprises a plurality of color filter portions, and each of the plurality of color filter portions is disposed within each of the plurality of first grooves.

15. The display panel according to claim 14, wherein the display panel further comprises a plurality of black matrixes, the plurality of the black matrixes are disposed on the encapsulation layer; each of the black matrix overlaps with each of the pixel definition layer in the orthographic projection on the substrate, the encapsulation layer further comprises a first inorganic layer, and the first inorganic layer is disposed on the organic encapsulation layer, the first inorganic layer covers the plurality of first grooves to form a plurality of second grooves, and each of the plurality of color filter portions is disposed within each of the plurality of second grooves.

16. The display panel according to claim 15, wherein a depth of each of the plurality of second grooves is equal to a thickness of each of the plurality of color filter portions; a surface of each of the plurality of color filter portions away from the substrate is coplanar with a surface of the first inorganic layer at a non-groove position on the side away from the substrate.

17. The display panel according to claim 16, wherein each of the plurality of black matrix partially overlaps with each of the plurality of color filter portions in the orthographic projection of the substrate.
